(19) United States
(12) Patent Application Publication
(10) Pub. No.: US 2008/0135084 A1
(43) Pub. Date: Jun. 12, 2008

(54) Sub-module photovoltaic control system

(76) Inventor: Ronald S. Scharlack, Brookline, MA (US)

Correspondence Address: WILMERHALE/NEW YORK, 399 PARK AVENUE, NEW YORK, NY, 10022, US

(21) Appl. No.: 11/636,911

(22) Filed: Dec. 11, 2006

(51) Int. Cl. H01L 31/042

(52) U.S. Cl. 136/244

(57) ABSTRACT

A method and apparatus for operating a photovoltaic cell array provide for collecting power generated by each group of at least one but less than all of the cells of the array using each of a plurality of controllers, one controller for each group; converting the collected power at each controller to have a common output parameter, the common output parameter value being greater than the value of the same parameter at each of the individual cells; and combining the outputs from the controllers to generate an output for the array. Each controller thus has connected to it a group of one or more, but less than all, of the photovoltaic cells of the array, and the outputs of the controllers are connected preferably in parallel but potentially in series as well. The cells connected to the controllers are also connected in series, parallel, or a combination of the two. In this manner, the array output can be at or near its optimum power with each group of photovoltaic cells operating near their peak performance and under operating conditions potentially different from each other group of photovoltaic cells.

### BACKGROUND OF THE INVENTION

The invention relates generally to photovoltaic systems, and in particular to methods and apparatus for improving the performance of arrays of photovoltaic cells.

Photovoltaic power systems typically consist of an array of one or more photovoltaic modules, and within each module are multiple photovoltaic cells. These cells produce low voltage DC current with the characteristic of a current source in parallel with a forward biased diode. Photovoltaic cells operate at maximum efficiency at an operating point that depends on the characteristics of the cell and operating conditions such as insolation and temperature. Because of the intrinsic low cell voltage, the cells are typically connected in series to produce a higher voltage without increasing the current, thereby reducing electrical resistive losses. Although it is desirable to connect cells in series for this reason, all series connected cells must conduct the same current. However, due to cell manufacturing variations, as well as variations in the insolation received by the cells within a module, the cells of the series connection will not all be operating at their ideal efficiency. This effect can be reduced by connecting some of the cells in parallel to average the operating conditions across a module. Furthermore, series cells that are shadowed (that is, operating in a lower impinging light environment) must be protected against potentially destructive reverse voltages by using diodes that can shunt current around a cell or a group of cells.

One efficient method for coupling a photovoltaic module to a load uses a switching regulator that adaptively maintains the module operating at its peak power point. Other power converters and control methodologies, all directed towards the use of a single controller for the many modules or arrays, have been used in the field.

Other methods for overcoming the limitation of conventional peak climbing controllers are also known. For example, one known method uses a genetic algorithm to determine the location of the peak operating point.

However, these variations in the operating characteristics of actual systems make efficient control of modules and arrays difficult and still results in efficiency loss.

### SUMMARY OF THE INVENTION

The invention relates to methods and apparatus for controlling and optimizing the output of a photovoltaic cell array having a plurality of photovoltaic cells. The method according to one embodiment of the invention, collects the power generated by each group of at least one but less than all of the cells of the array using a plurality of controllers. One controller is provided for each group of photovoltaic cells. The method further features converting the power collected at each controller to have a common output parameter (such as voltage or current), the value of the common output parameter being greater than the value of the same parameter for each of the individual cells. The method also features combining the outputs of the controllers to generate an output power for the array.

The apparatus of the invention, the photovoltaic cell array power control system, has a module having a plurality of photovoltaic cells arranged in a physically adjacent array of cells. A plurality of controllers, each controller being connected to a different group of (one or more) electrically connected photovoltaic cells at their controller inputs, and the controllers being interconnected with each other at their outputs, the number of controllers being typically less than the number of photovoltaic cells, and greater than one. Thereby, each group of photovoltaic cells associated with a controller is operated at an operating point set solely for that group of photovoltaic cells by the connected and associated controller.

Photovoltaic cells can be operated at maximum efficiency if individual cells, or groups of cells, which have similar insolation, temperature and performance characteristics, are operated independently by separate controllers. According to an embodiment of the invention, there is provided a circuitry for enabling the maximum performance of cells, modules and arrays by combining the optimized outputs of multiple individual cells, and/or multiple groups of cells, using multiple controllers. The apparatus and method avoid the resistive bias losses associated with parallel cell operation by converting the low voltage output of the cells and/or groups of cells into higher voltage using DC to DC or DC to AC converters. Each voltage converter optimizes the output of its associated cell or cells. Each converter controls the voltage output by using peak hunting techniques as are well known within the field of photovoltaic array control. One such method is referred to as peak climbing. Since each cell or group of cells is maintained at or near optimal peak power operation point, destructive reverse bias conditions are avoided. Furthermore, shadowed cells can be operated efficiently even though at reduced power output. Cells groups can extend across modules if desired. The method and apparatus of the invention can be utilized, for example, with flat-panel or concentrator modules.

### BRIEF DESCRIPTION OF THE DRAWINGS

Other objects and features of the invention will be apparent from the drawings in which:

FIG. 1 is an equivalent circuit model of a photovoltaic cell;

FIG. 2a is a simplified circuit illustrating control of individual cells in accordance with the invention:

FIG. 2b is a simplified diagram showing control of multiple cells connected in parallel within a module in accordance with the invention;

FIG. 2c is simplified circuit showing control of multiple cells connected in series within a module in accordance with the invention:

FIG. 2d is a simplified circuit showing control of multiple cells connected in parallel between modules in accordance with the invention;

FIG. 2e is a simplified circuit showing control of multiple cells connected in series between modules in accordance with the invention; and

FIG. 2f is a circuit showing control of multiple series and parallel connected cells within a module in accordance with the invention.

### DETAILED DESCRIPTION OF THE INVENTION

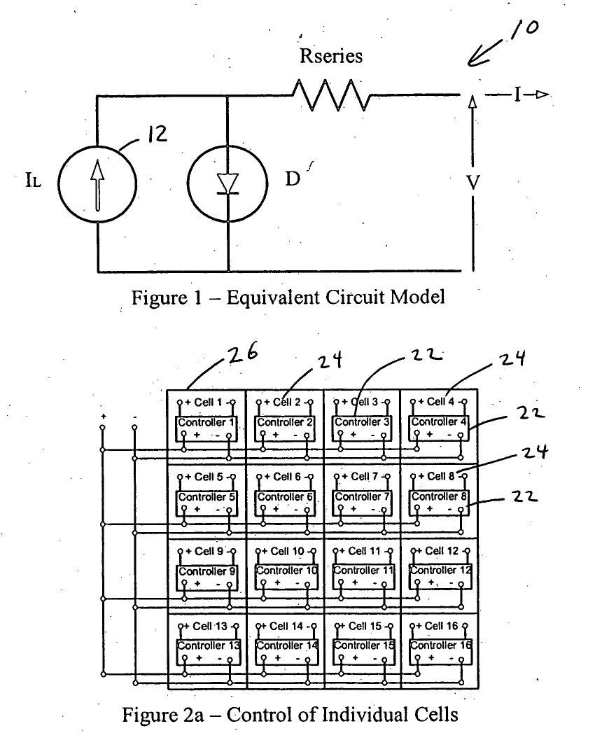

Referring to FIG. 1, the operating characteristics of a typical photovoltaic cell 10 can be derived from the simplified model shown in FIG. 1, where I_{L} is the photovoltaic current from a current generator 12, D is an ideal forward biased diode, I is the current output, V is the output voltage and Rₛₑᵣᵢₑₛ is the resistance of a series resistance 14.

The simplified equation, describing the current-voltage (I-V) relationship of a photovoltaic cell, is given in Equation 1,

$$I = {I}_{L} - {I}_{o} \cdot [ {e}^{\frac{q}{AkT} \cdot ( V - 1 \cdot {R}_{series} )} - 1 ]$$

$$Equation 1 - Current \text{-} Voltage Relationship$$

where I_{L}, as before, is the photovoltaic cell current, Iₒ is the diode saturation current, A is a constant value characteristic of the cell, q is the value of an electronic charge, k is Boltzmann's constant, and T is the absolute temperature of the cell. The reverse bias condition is not included since it must be prevented to avoid cell destruction.

Since each cell can have slightly different characteristics (Iₒ, Rₛₑᵣᵢₑₛ and A) as well as difference insolation (indirectly represented by I_{L}) and temperature, the resulting ideal operating points of cells in the same array can vary considerably under real operating conditions.

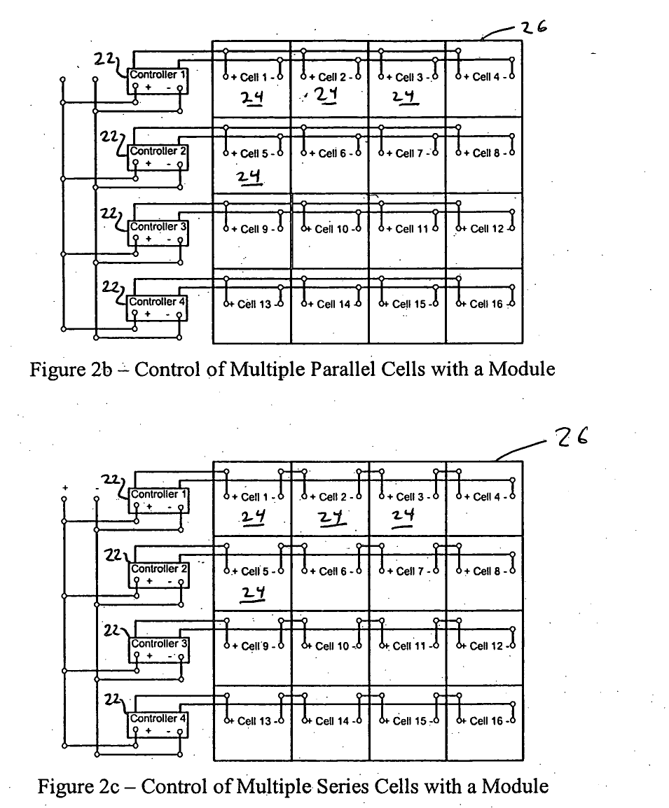

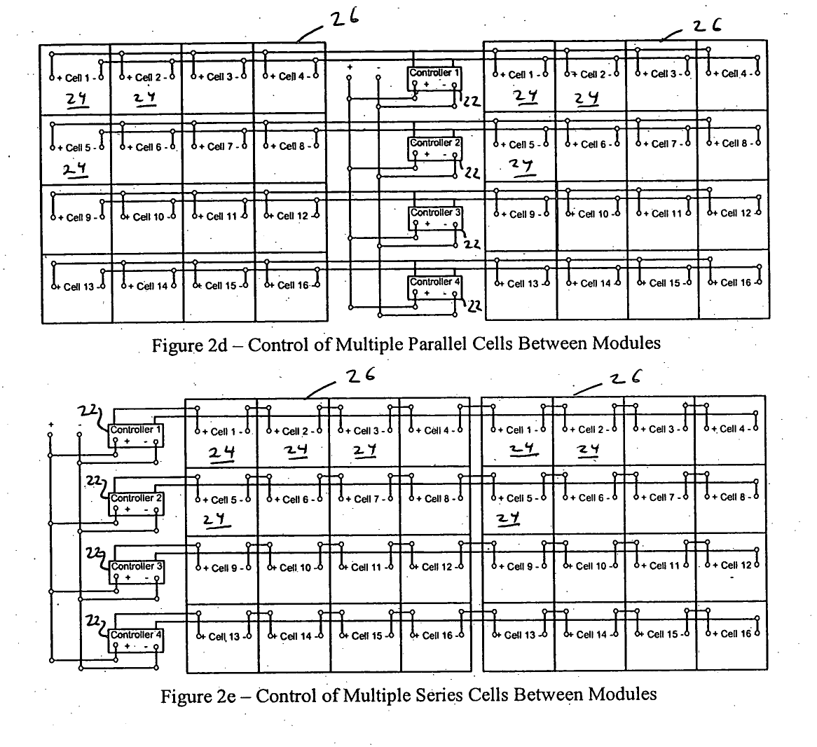

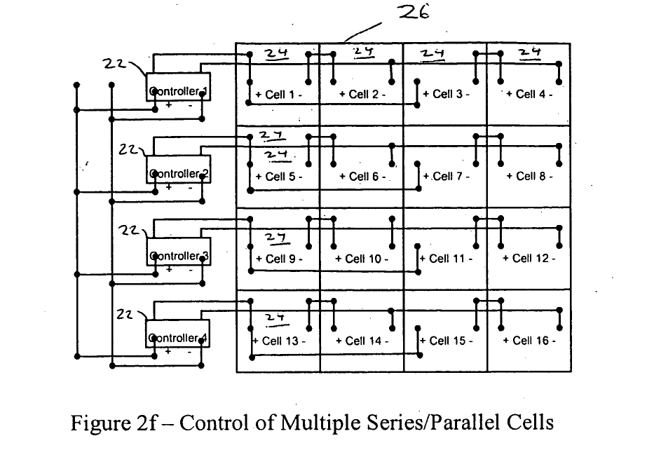

Although the best efficiency is achieved by dedicating one controller to operate with each cell, relatively efficient control can be achieved if cells with common operating characteristics or operating conditions, such as shadowing, are operated together. Thus, the relative cost of the controllers is reduced by using each controller to control multiple but not all cells. Cells can be either connected to a controller in parallel, in series, or in a combination of the two. The controller outputs are typically connected in parallel, although other interconnections can be used. FIGS. 2a, 2b, 2c, 2d, 2e and 2f show some of the options for connecting and controlling individual cells, such as providing one controller for each cell (FIG. 2a), multiple cells within a single module controlled by one controller (FIG. 2b (parallel connections) and FIG. 2c (series connections)), multiple cells across more than one module controlled by one controller (FIG. 2d (parallel connections) and FIG. 2e (series connections), and a mixture of parallel and series connections (FIG. 2f)). As illustrated, the multiple controllers are then connected together, in parallel, so that the currents add. Generally, the voltage output of each controller should be higher than the voltage received by the controller from the cells. This configuration reduces the current handled by the cells, and thereby reduces resistive losses, and, as a result, the size and cost of the interconnections required. (The controllers are well known in the field, and can be, for example, Solar Boost, manufactured by Blue Sky Energy or T80 Turbocharger, manufactured by Apollo Solar.)

Referring to FIGS. 2a-2f, each figure shows multiple controllers 22, each controller connected to one or more, but not all, of the photovoltaic cells 24 in a module 26, or across modules 26. The illustrated controllers 22 are connected at their outputs in parallel so that their output voltages are the same and their currents add. Each controller acts to convert the voltage and current received from the one or more cells to which it is connected to a common output voltage, typically higher than the voltage input to the converters, the current varying in accordance with the power being provided by the cells. For example, the voltage is approximately 13.6 VDC for a simple battery charging application, or approximately 48 VDC or 115 VAC 60 Hz for larger power systems.

The photovoltaic cells on the other hand each operate either individually as in FIG. 2a or as a collection or group as illustrated in the remaining FIGS. 2b-2f. In the case of parallel connections as shown in FIGS. 2b, 2d and in part of 2f, the cells of a group, which are connected in parallel, all have the same output voltage, and their currents adding in the parallel connection. Alternatively, as illustrated in Figures in 2c, 2e, and part of FIG. 2f, the series connected cells all pass the same current, but their voltages add. In either instance, the controllers, as is well known in the field of photovoltaic cells, act to convert the input voltage, whatever it may be set at, to a common higher output voltage with the current scaling down accordingly. This is illustrated for both the series and parallel, or series/parallel connections. It is important to note that for any of the physical configuration interconnections, whether a group of cells in a row, or a two dimensional group of cells, the outputs are connected to a controller and the controllers are interconnected, preferably in parallel as illustrated.

In operation, each of the controllers 24 acts to convert what the input power, no matter what its voltage and current, to a common previously selected, output voltage (if connected in parallel) or output current (if connected in series). The result therefore is a plurality of controllers each having a common parameter (voltage or current) at their outputs and operating internally to convert the power input to that common parameter value, while controlling the operating point of its associated group of cells. Thus, for example, as the voltage output of the cells connected to the controller shown, for example, in FIG. 2b decreases, the voltage output of each controller stays the same but the controller current output would decrease accordingly. In this manner, each of the cells can operate within their connection group at an optimum level (under substantially similar operating conditions) as the controller, at its input, sets either the current or voltage, depending upon whether it is connected to the cells in parallel or series or a combination of the two, to an optimum operating point for the group of cells connected to it.

It will be apparent to one practiced in this field that variations and modifications of the above described embodiments are contemplated and are within the scope of the invention.

What is claimed is:

1. A method for operating a photovoltaic cell array having a plurality of photovoltaic cells, comprising
collecting the power generated by each group of at least one but less than all of the cells of the array using a plurality of controllers one controller for each group;
converting the power collected at each controller to have a common output parameter, the common output parameter value being greater than the value of the same parameter for each of the individual cells; and
combining the outputs of the controllers to generate an output power of the array.

2. The method of claim 1 further comprising
connecting a different plurality of physically adjacent cells to each controller, the physical relationship being determined so that each of the cells of each plurality has similar operating characteristics.

3. The method of claim 2 further comprising
connecting each said cells of each plurality of cells in one of a series connection, a parallel connection, or a series/parallel connection.

4. The method of claim 2 further comprising
selecting the photovoltaic cells connected to a controller to be physically adjacent to each other and thereby forming a one dimensional, or a two dimensional geographical physical configuration.

5. The method of claim 1 further comprising
connecting said controllers to photovoltaic cells across individual modules, each module having a plurality of photovoltaic cells.

6. A photovoltaic cell array power control system comprising
a module having a plurality of photovoltaic cells arranged in a physically adjacent array of cells; and
a plurality of controllers, each controller being connected to a different group of electrically connected photovoltaic cells at their inputs and being interconnected with each other at their outputs, the number of controllers being greater than one;
whereby each group of photovoltaic cells associated with a controller operates at an operating point set solely for the photovoltaic cells of the group connected to the associated controller.

7. The photovoltaic power system of claim 6 wherein each group has one photovoltaic cell.

8. The photovoltaic power system of claim 6 wherein the number of controllers is less than the number of photovoltaic cells, and each group has at least two photovoltaic cells.

9. The photovoltaic power system of claim 8 wherein
the photovoltaic cells of a group are connected to a controller in one of a parallel connection, a series connection, or a series/parallel connection.

10. The photovoltaic power system of claim 8 further wherein
the photovoltaic cells are arranged in a one dimensional and/or a two dimensional sub-array.
